(19) United States
(12) Patent Application Publication
(10) Pub. No.: US 2010/0230276 A1
(43) Pub. Date: Sep. 16, 2010

(54) DEVICE AND METHOD FOR THIN FILM DEPOSITION USING A VACUUM ARC IN AN ENCLOSED CATHODE-ANODE ASSEMBLY

(75) Inventors: Yitzhak I. Beilis, Lod (IL); Reuven Lev Boxman, Herzliya (IL); Alexey Shashurin, Tel Aviv (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: Ramot AT Tel Aviv University Ltd., Tel Aviv (IL)

(21) Appl. No.: 12/305,970

(22) PCT Filed: Jul. 8, 2007
(86) PCT No.: PCT/IL07/00849

§ 371 Date: Dec. 21, 2008

Related U.S. Application Data
(60) Provisional application No. 60/806,625, filed on Jul. 6, 2006.

(51) Int. Cl. C23C 14/32

(52) U.S. Cl. 204/192.38; 204/298.41

(57) ABSTRACT

A vacuum-arc device including: a consumable cathode including a first material having a defined active surface, a refractory anode including a second material, an inter-electrode volume, bounded partially by at least a portion of an inner wall of the cathode and by at least a portion of an inner wall of the anode, wherein at least a portion of the inner walls form a first chamber surrounding the inter-electrode volume, the chamber having at least one opening fluidly communicating between the inter-electrode volume and an a volume outside the chamber; a vacuum chamber, disposed around and communicating with the first chamber; an evacuation mechanism for evacuating the vacuum chamber; wherein the cathode is adapted, and the cathode and the anode are disposed, such that upon evacuating the vacuum chamber using the evacuation mechanism, ignition of an arc discharge between the cathode and the anode, and activation of a high-current power supply, a portion of the first material is liberated from the cathode, transported through the inter-electrode volume, and discharged from the first chamber through the opening, wherein: a total opening area of the at least one opening, Aopenings, is defined by a sum of a minimum cross-sectional area for each the opening, the cross-sectional area being normal to a path of the opening between the inter-electrode volume and the volume outside the chamber; a surface area of the anode, Aanode, is defined by a geometrical surface area of the portion of the anode that bounds the inter-electrode volume; and wherein a ratio of the surface area of the anode to the total opening area, A_{anode}/A_{openings} is at least 10.

### FIELD AND BACKGROUND OF THE INVENTION

The present invention relates to vacuum-arc deposition of thin films and, more particularly, to a method and device for vacuum-arc deposition of thin films by means of a high-density plasma within an enclosed anode-cathode assembly.

Vacuum arc generated plasma has numerous important technological applications. The most common applications, deposition of metallic and ceramic thin films and metallic ion implantation, utilize the cathodic supersonic plasma jet. For many applications, uniform, smooth and continuous films are required. Very high quality metallic films are necessary for various modern technologies and, in particular, for optical and microelectronic applications. Such high quality films cannot be produced using the vacuum arc plasma jet directly, because the plasma contains liquid droplets or solid particles, commonly called macroparticles. Some of the macroparticles may become incorporated into the coatings, degrading their quality. Consequently, macroparticle contamination is a major disadvantage of vacuum arc plasma jet technologies. To overcome this problem, the plasma jet may be guided from the cathode past an obstacle that blocks the macroparticles and hence to the substrate by a curved magnetic field, to produce macroparticle free coatings (see I. Aksenov et al., Sov. J. Plasma Phys., 4, 1978, 425). However, plasma transmission through a curved plasma guide generally results in excessive plasma losses in comparison with plasma transmission through a straight duct.

Recently, considerable experimental efforts have been applied to reduce plasma losses during transport. In particular, significant influence of positive duct bias on plasma transmission through toroidal ducts has been reported. However, in spite of the recent progress, the plasma losses in the filtered systems are relative high, such that most of cathode material is lost in the curved channel.

Another type of vacuum arc plasma source is based on a hot electrode vacuum arc. In the hot anode vacuum arc (HAVA), the metallic plasma is produced by the evaporation of anode material. In this mode of arc production, the arc current heats the anode until the temperature reaches sufficiently high values such that the anode surface becomes an intensive source of vapor that may have a reduced content of droplets and other macroparticles. The macroparticle content in the HAVA metal vapor plasma is significantly less than in cathode spot and anode spot vacuum arcs. The main challenge in using this method is to find the arc parameters that minimize macroparticle production.

The cathode material of HAVA plasma sources is usually selected to be less volatile than that of the anode. In contrast, a more recent discharge mode in a cell having a refractory anode and volatile cathode is taught by U.S. Pat. No. 6,391,164 to Beilis et al. [see also Rosenthal, et al., J. Phys. D.: Appl. Phys. 28, N1, 353 (1995); Beilis et al. Physics of Plasmas 7, N7, 3068 (2000)], all of which are incorporated by reference for all purposes as if fully set forth herein. In this discharge mode, sometimes referred to as a hot refractory anode vacuum arc (HRAVA), material evaporated from the cathode is transported to the anode. As the arc develops, two phenomena occur: i) anode heating and ii) re-evaporation of the cathode material deposited on the anode during an initial period of operation. As the HRAVA evolves, an intensely radiating plasma plume is created at the anode surface, expanding with time in the axial and radial directions. The HRAVA plasma is sufficiently hot and dense to facilitate evaporation of the macroparticles produced by the cathode spots during the passage of the macroparticles through the inter-electrode gap [see Beilis et al., J. Phys. D: Appl. Phys., Vol. 32, No 1, 1999 (pp. 153-158)]. The radially expanding HRAVA plasma has the potential to be used as a plasma source with reduced macroparticle content in various technological applications, and more particularly, in thin-film deposition [see Beilis et al., Surface and Coatings Technology, 133-134, issues 1-3, 2000, p. 91-95].

Although considerable progress has been made in vacuum arc plasma deposition utilizing the metallic vapor generated in the cathode spot, the efficiency and the plasma quality of the known arc plasma generation devices and methods appear to be insufficient.

It would certainly be highly advantageous to have a cathode-based, vacuum arc plasma deposition device and method that display characteristically improved arc plasma generation efficiencies and improved plasma quality.

### SUMMARY OF THE INVENTION

According to the teachings of the present invention there is provided a vacuum-arc device including: a consumable cathode including a first material having a defined active surface, a refractory, substantially non-consumable anode, associated with the cathode, the anode including a second material, an inter-electrode volume, bounded partially by at least a portion of an inner wall of the cathode and by at least a portion of an inner wall of the anode, wherein at least a portion of the inner walls form, at least in part, a first chamber surrounding the inter-electrode volume, the chamber having at least one opening fluidly communicating between the inter-electrode volume and an a volume outside the chamber; a vacuum chamber, disposed around and communicating with the first chamber; an evacuation mechanism for evacuating the vacuum chamber; the anode and the cathode for connecting to a high-current power supply, wherein the cathode is adapted, and the cathode and the anode are disposed, such that upon evacuating the vacuum chamber using the evacuation mechanism, ignition of an arc discharge between the cathode and the anode, and activation of the high-current power supply, a portion of the first material is liberated from the defined active surface of the cathode, transported through the inter-electrode volume, and discharged from the first chamber through the at least one opening, wherein: a total opening area of the at least one opening, A_{openings}, is defined by a sum of a minimum cross-sectional area for each the opening, the cross-sectional area being normal to a path of the opening between the inter-electrode volume and the volume outside the chamber; a surface area of the anode, A_{node}, is defined by a geometrical surface area of the portion of the anode that bounds the inter-electrode volume; and wherein a ratio of the surface area of the anode to the total opening area,

A_{node}/A_{openings}

is at least 10.

According to another aspect of the present invention there is provided a vacuum-arc device including: a consumable cathode including a first material and having a defined active surface, a refractory, substantially non-consumable anode, associated with the cathode, the anode including a second material, an inter-electrode volume, bounded partially by at least a portion of an inner wall of the cathode and by at least a portion of an inner wall of the anode, wherein at least a portion of the inner walls form, at least in part, a first chamber surrounding the inter-electrode volume, the chamber having at least one opening fluidly communicating between the inter-electrode volume and an a volume outside the chamber; a vacuum chamber, disposed around and communicating with the first chamber; an evacuation mechanism for evacuating the vacuum chamber; the anode and the cathode for connecting to a high-current power supply, wherein the cathode is adapted, and the cathode and the anode are disposed, such that upon evacuating the vacuum chamber using the evacuation mechanism, ignition of an arc discharge between the cathode and the anode, and activation of the high-current power supply, a portion of the first material is liberated from the defined active surface of the cathode, transported through the inter-electrode volume, and discharged from the first chamber through the at least one opening, wherein: a surface area of the cathode, A_{cathode}, is defined by a geometrical surface area of the portion of the cathode that bounds the inter-electrode volume; a surface area of the anode, A_{anode}, is defined by a geometrical surface area of the portion of the anode that bounds the inter-electrode volume; and wherein a ratio of the surface area of the anode to the surface area of the cathode,

A_{anode}/A_{cathode}

is at least 2.0.

According to yet another aspect of the present invention there is provided a method of producing a plasma jet using a vacuum-arc device, the method including: (a) providing a device including: a consumable cathode including a first material and having a defined active surface, a refractory, substantially non-consumable anode, associated with the cathode, the anode including a second material, the cathode and the anode relatively disposed so as to form an inter-electrode volume, the inter-electrode volume bounded partially by at least a portion of an inner wall of the cathode and by at least a portion of an inner wall of the anode, wherein at least a portion of the inner walls form, at least in part, a first chamber surrounding the inter-electrode volume, the chamber having at least one opening fluidly communicating between the inter-electrode volume and an a volume outside the chamber; a total opening area of the at least one opening, A_{openings}, is defined by a sum of a minimum cross-sectional area for each the opening, the cross-sectional area being normal to a path of the opening between the inter-electrode volume and the volume outside the chamber; a surface area of the anode, A_{anode}, is defined by a geometrical surface area of the portion of the anode that bounds the inter-electrode volume; and wherein a ratio of the surface area of the anode to the total opening area,

A_{anode}/A_{openings}

is at least a predetermined ratio; (b) at least partly evacuating the chamber, and (c) establishing an arc discharge between the cathode and the anode, using a high-current power supply, such that the discharge produces a vapor, the vapor including vaporized cathode material, wherein the predetermined ratio is sufficiently high such that substantially all macroparticles from the first material are evaporated prior to being discharged from the first chamber via the at least one opening.

According to yet another aspect of the present invention there is provided a vacuum-arc device including: a consumable cathode including a first material having a defined active surface, a refractory, substantially non-consumable anode, associated with the cathode, the anode including a second material, an inter-electrode volume, bounded partially by at least a portion of an inner wall of the cathode and by at least a portion of an inner wall of the anode, wherein at least a portion of the inner walls form, at least in part, a first chamber surrounding the inter-electrode volume, the chamber having at least one opening fluidly communicating between the inter-electrode volume and an a volume outside the chamber; the anode and the cathode for connecting to a high-current power supply, wherein the cathode is adapted, and the cathode and the anode are disposed, such that upon evacuating the chamber, ignition of an arc discharge between the cathode and the anode, and activation of the high-current power supply, a portion of the first material is liberated from the defined active surface of the cathode, transported through the inter-electrode volume, and discharged from the first chamber through the at least one opening, as a thrust-producing plasma jet, wherein: a total opening area of the at least one opening, A_{openings}, is defined by a sum of a minimum cross-sectional area for each the opening, the cross-sectional area being normal to a path of the opening between the inter-electrode volume and the volume outside the chamber; a surface area of the anode, A_{anode}, is defined by a geometrical surface area of the portion of the anode that bounds the inter-electrode volume; and wherein a ratio of the surface area of the anode to the total opening area,

A_{anode}/A_{openings}

is at least 10.

According to further features in the described preferred embodiments, the inter-electrode volume is further bounded by an electrical insulator so as to electrically insulate between the anode and the cathode.

According to still further features in the described preferred embodiments, the electrical insulator contacts both the anode and the cathode.

According to still further features in the described preferred embodiments, the electrical insulator contacts both the anode and the cathode so as to seal a portion of the inter-electrode volume from the volume outside the chamber.

According to still further features in the described preferred embodiments, the electrical insulator includes boron nitride.

According to still further features in the described preferred embodiments, the electrical insulator consists essentially of boron nitride.

According to still further features in the described preferred embodiments, the electrical insulator is boron nitride.

According to still further features in the described preferred embodiments, the at least one opening passes through the anode.

According to still further features in the described preferred embodiments, the vacuum-arc device further includes: at least one insert disposed in the at least one opening, the insert for increasing tortuousity of a path of particles of the portion of the first material as the particles are discharged through the opening.

According to still further features in the described preferred embodiments, the insert is adapted to obstruct a line of sight between the active surface of the cathode and at least one of the at least one opening.

According to still further features in the described preferred embodiments, the cathode is adapted, and the cathode and the anode are disposed, such that the portion of the first material being discharged through the at least one opening is discharged as a plasma jet.

According to still further features in the described preferred embodiments, the plasma jet is for coating a substrate.

According to still further features in the described preferred embodiments, the vacuum-arc device further includes: a mechanism for mounting at least one substrate for coating by plasma discharged through the opening, the mechanism having a defined position for disposing the substrate.

According to still further features in the described preferred embodiments, the mechanism is disposed with respect to the opening such that the defined position is in a line of sight of the opening.

According to still further features in the described preferred embodiments, the vacuum-arc device further includes: a substrate, disposed in a line of sight of the opening.

According to still further features in the described preferred embodiments, the second material has a higher melting temperature than the first material, and the second material has a lower equilibrium vapor pressure than the first material at every temperature in a range above the melting temperature of the first material and below the melting temperature of the second material.

According to still further features in the described preferred embodiments, the opening passes through the anode, such that during operation of the device, plasma disposed in the inter-electrode volume is discharged through the opening, along the line of sight, towards the defined position for disposing the substrate.

According to still further features in the described preferred embodiments, a surface area of the cathode, A_{cathode}, is defined by a geometrical surface area of the portion of the cathode that bounds the inter-electrode volume, and wherein a ratio of the surface area of the anode to the surface area of the cathode,

A_{node}/A_{cathode}

is at least 2.0.

According to still further features in the described preferred embodiments, the ratio of the surface area of the anode to the surface area of the cathode is at least 2.5.

According to still further features in the described preferred embodiments, the ratio of the surface area of the anode to the surface area of the cathode is at least 3.5.

According to still further features in the described preferred embodiments, the ratio of the surface area of the anode to the surface area of the cathode is at least 5.

According to still further features in the described preferred embodiments, the ratio of the surface area of the anode to the surface area of the cathode is at least 6.

According to still further features in the described preferred embodiments, the ratio of the surface area of the anode to the total opening area is at least 20.

According to still further features in the described preferred embodiments, the ratio of the surface area of the anode to the total opening area is at least 30.

According to still further features in the described preferred embodiments, the ratio of the surface area of the anode to the total opening area is at least 50.

According to still further features in the described preferred embodiments, the ratio of the surface area of the anode to the total opening area is at least 60.

According to still further features in the described preferred embodiments, the ratio of the surface area of the anode to the total opening area is at least 100.

According to still further features in the described preferred embodiments, the ratio of the surface area of the anode to the total opening area is at least 150.

According to still further features in the described preferred embodiments, at least one of the at least one opening is outside of a line of sight of the active surface of the cathode.

According to still further features in the described preferred embodiments, each at least one opening is outside of a line of sight of the active surface of the cathode.

According to still further features in the described preferred embodiments, the vacuum-arc further includes: at least one insert disposed in the at least one opening, the insert for increasing tortuousity of a path of particles of the portion of the first material as the particles are discharged through the opening.

According to still further features in the described preferred embodiments, the insert is adapted to completely obstruct a line of sight between the active surface of the cathode and at least one of the at least one opening.

According to still further features in the described preferred embodiments, the insert has orthogonal, interconnecting openings.

According to still further features in the described preferred embodiments, a face of the insert facing the cathode is devoid of the orthogonal openings.

According to still further features in the described preferred embodiments, the method further includes: (d) exposing a substrate to the vaporized cathode material produced by the arc discharge, so as to coat the substrate.

According to still further features in the described preferred embodiments, the ratio of the surface area of the anode to the total opening area is sufficiently high such that a density of heavy particles in the first chamber is at least 2·10¹⁵ particles per cubic centimeter.

According to still further features in the described preferred embodiments, the ratio of the surface area of the anode to the total opening area and the ratio of the surface area of the anode to the surface area of the cathode are sufficiently high such that a density of heavy particles in the first chamber is at least 5·10¹⁵ heavy particles per cubic centimeter.

According to still further features in the described preferred embodiments, the ratio of the surface area of the anode to the total opening area and the ratio of the surface area of the anode to the surface area of the cathode are sufficiently high such that a density of heavy particles in the first chamber is at least 8·10¹⁵ particles per cubic centimeter.

According to still further features in the described preferred embodiments, the ratio of the surface area of the anode to the total opening area and the ratio of the surface area of the anode to the surface area of the cathode are sufficiently high such that a density of heavy particles in the first chamber is at least 1·10¹⁶ particles per cubic centimeter.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. Throughout the drawings, like-referenced characters are used to designate like elements.

In the drawings:

FIG. 1 is a schematic cross-sectional view of a hot refractory anode vacuum arc (HRAVA) device of the prior art;

FIG. 2a is a schematic, conceptual representation of a first embodiment of an inventive vacuum arc device having a chamber containing the inter-electrode vapor volume, the chamber having a single opening through the anode;

FIG. 2b is a schematic, conceptual representation of another embodiment of the inventive vacuum arc device, in which the chamber has an additional opening disposed between the walls of the anode and cathode;

FIG. 2c is a schematic, simplified representation of the HRAVA vacuum arc device of FIG. 1;

FIG. 2d is a schematic, cross-sectional view of the first embodiment of the inventive vacuum arc device, shown in greater detail;

FIG. 2e is a photograph showing the discharge of a plasma jet from the inventive vacuum arc device of FIG. D, taken 45 seconds after the initial arc formation;

FIGS. 3a-3b are schematic representations of a cylindrical insulating insert disposed within a refractory anode, the insert having passageways or openings disposed radially with respect to the overall flow of plasma through the chamber, and an axial opening for the flow of plasma therethrough (and towards the substrate surface), according to another embodiment of the present invention;

FIG. 3c is a schematic representation of the insulating insert of FIGS. 3a-3b.

FIGS. 4a-4b are schematic representations of a cylindrical anode arrangement, the anode having openings disposed radially with respect to the overall flow of plasma through the chamber, and an axial opening for the flow of plasma therethrough (and towards the substrate surface), according to another embodiment of the present invention.

FIG. 4c is a schematic representation of cylindrical anode of FIGS. 4a-4b;

FIG. 5 is a graph showing film thickness distribution using a hollow hot anode having radially disposed holes, according to the present invention;

FIG. 6 is a graph showing deposition rate as a function of arc current using a hollow hot anode, such as the anode used in FIG. 5, and

FIG. 7 is a schematic representation of a hollow hot graphite anode having passageways disposed in axial (collinear) fashion with respect to the overall flow of plasma through the chamber, according to another embodiment of the present invention.

### DESCRIPTION OF THE PREFERRED EMBODIMENTS

One aspect of the present invention is a method and device for vacuum-arc deposition of thin films by means of a black-body anode-cathode assembly.

The principles and operation of the method and device of the present invention may be better understood with reference to the drawings and the accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

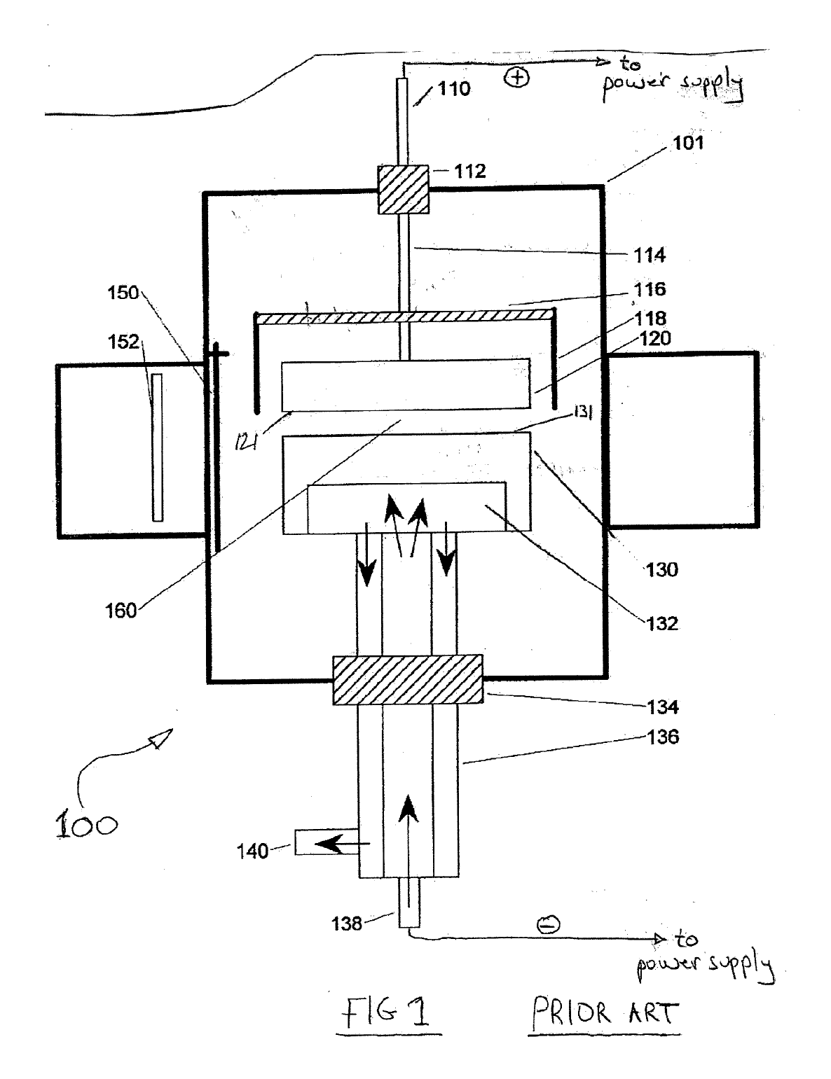

Referring now to the drawings, FIG. 1 is a schematic cross-sectional view of a hot refractory anode vacuum arc (HRAVA) device 100 of the prior art. An electrical arc is ignited between a cooled source cathode 130, and a non-consumable thermally isolated anode 120. The cathode is preferably cooled by a flow of water to a back side of cathode 130. The flow of water may be provided via a cavity 132 within cathode 130. Cavity 132 is supplied by a flow of water via a coaxial pipe 136 having a water inlet 138 and a water outlet 140. The arrows within pipe 136 and cavity 132 show the general direction of the water flow.

Anode 120, constructed from a refractory material, is mechanically supported by a rod 114, which also provides the electrical connection between anode 120 and the rest of the arc circuit. In a preferred embodiment, heat loss by radiation is reduced by surrounding anode 120 by a heat reflector 118. An insulating plate 116 serves both as a heat reflector for the top surface of anode 120, and as an insulator for insulating heat reflector 118 from the anode circuit.

Structures 110 and 136, which respectively provide mechanical support and electrical connection to anode 120 and cathode 130, are electrically insulated from a surrounding vacuum chamber 101 by insulated feedthroughs 112 and 134. Structures 110 and 136 are connected respectively to the positive and negative poles of a current source, which is not shown. A low voltage current source such as an arc welder may be employed. Some conventional means must be employed to initiate the arc, as the breakdown voltage in vacuum is very high.

Initially, the arc operates in the normal cathode spot mode, producing plasma jets that convey cathode material with a distribution that is peaked in the direction of the anode and in all other directions. In addition, macroparticles are produced, which are known to have a distribution that typically is peaked at a small angle with respect to the cathode plane. Thus, initially much of the cathode material produced by the arc is deposited on the anode, which is initially cool. When there is an unobstructed path from the cathode surface to a substrate 152, substrate 152 receives a flux of material that disadvantageously includes macroparticles.

The arc, however, heats the anode. If a sufficiently high arc current is supplied for a sufficiently long time, an inner surface 121 of anode 120 reaches a sufficiently high temperature such that any material previously deposited thereon (from cathode 130) is evaporated and no further deposition accumulates on inner surface 121. Consequently the production of macroparticles from the arc ceases or is greatly reduced.

If the flux of macroparticles from the initial stage of the arc (during cathode spot mode) can be prevented, the coating formed on substrate 152 is substantially free of macroparticles. The flux may be prevented by placing a shutter 150 between the arc sustained in an inter-electrode volume 160 and substrate 152. Shutter 150 is closed during the initial phase of the arc, and is opened only after the HRAVA mode is established.

As used herein in the specification and in the claims section that follows, the term “inter-electrode volume” refers to a vapor space bounded by the anode-cathode vacuum arc pair and by an electrical insulator or electrically insulating material disposed therebetween.

In the absence of such insulation material, when the anode and cathode of the anode-cathode vacuum arc pair are spaced apart (set apart at a distance), the term “inter-electrode volume” refers to a vapor space bounded by the anode-cathode vacuum arc pair, when the perimeter of the anode is connected to the perimeter of the cathode by straight imaginary lines. The one or more open areas at the surface of the inter-electrode volume are considered to be “openings” or “apertures” in the inter-electrode volume or chamber.

As used herein in the specification and in the claims section that follows, the term “anode surface area”, “surface area of the anode”, and the like, refers to the geometrical surface area of the portion of the anode that contacts the inter-electrode volume.

As used herein in the specification and in the claims section that follows, the term “cathode surface area”, “surface area of the cathode”, and the like, refers to the geometrical surface area of the portion of the cathode that contacts the inter-electrode volume.

As used herein in the specification and in the claims section that follows, the term “insulator surface area”, “surface area of the insulator”, and the like, refers to the geometrical surface area of the portion of the electrical insulator that contacts the inter-electrode volume.

As used herein in the specification and in the claims section that follows, the term “insulator”, with respect to an anode-cathode vacuum arc pair, refers to a material disposed so as to electrically insulate between the anode and the cathode of the anode-cathode vacuum arc pair.

We have discovered a new type of vacuum arc plasma source for obtaining a direct, high-quality plasma jet, and have named this source Vacuum Arc Black Body Assembly (VABBA). Various inventive cathode-anode configurations may be employed to produce this direct, high-quality plasma jet, examples of will be provided and described hereinbelow.

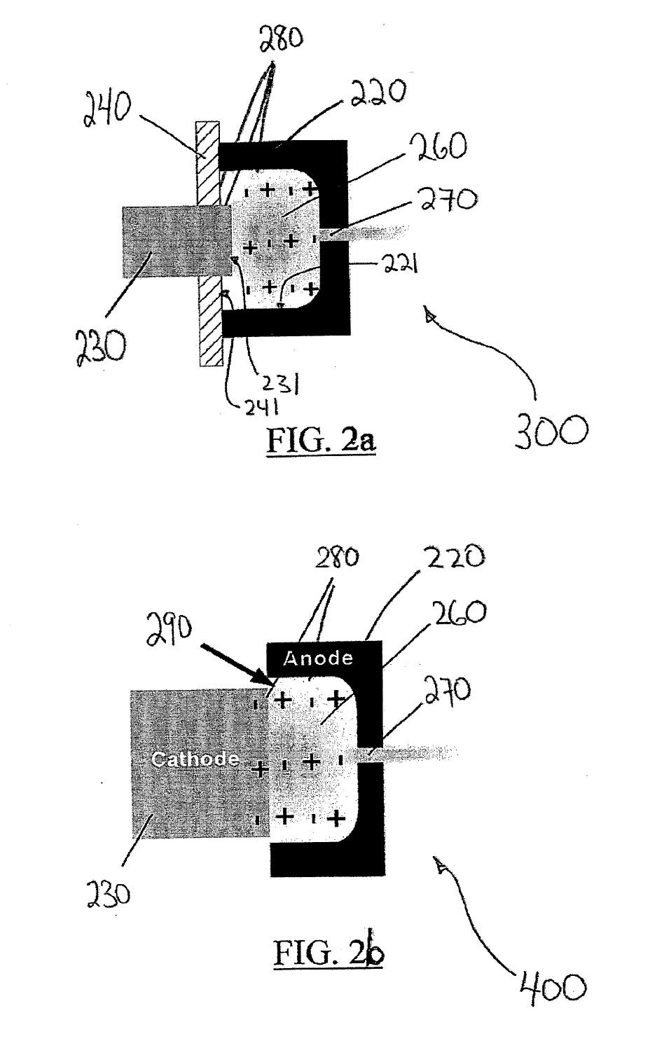

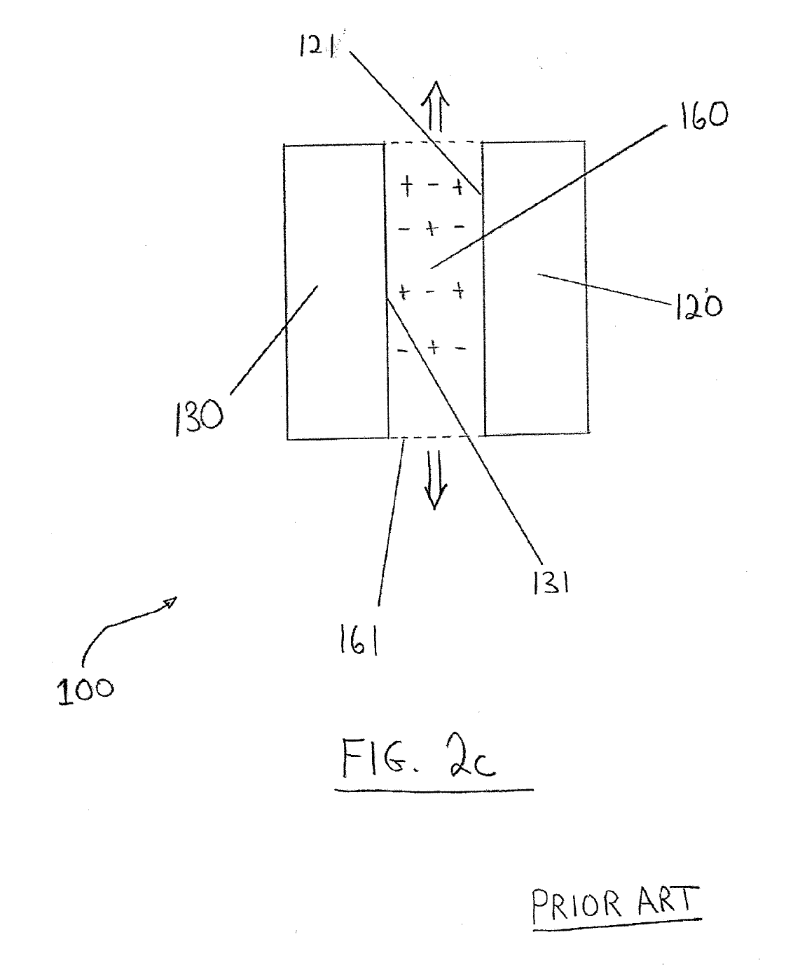

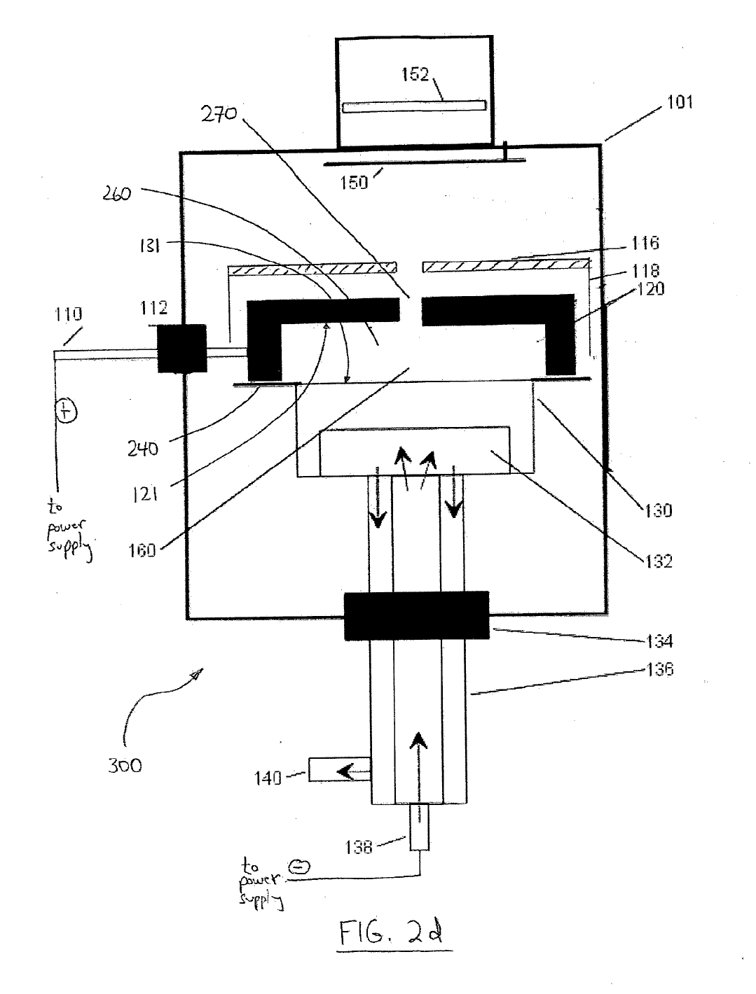

Referring now to FIGS. 2a-2b and 2d, FIG. 2a is a schematic representation of a first embodiment of a vacuum arc device 300 having a single opening in the chamber wall, according to the present invention.

Vacuum arc device 300 includes a source cathode 230, and a substantially non-consumable anode 220. Contained between cathode 230 and anode 220 is an inter-electrode vapor volume 260, through which the arc discharge is effected, and through which plasma from source cathode 230 is transported before ultimately exiting inter-electrode vapor volume 260 via aperture or opening 270.

Inter-electrode vapor volume 260 is contained within a chamber wall 280 made up of at least an inner surface 221 of anode 220 and an inner surface 231 of cathode 230. Vacuum arc device 300 may advantageously have an electrical insulator 240 disposed between cathode 230 and anode 220, as shown in FIG. 2a. An inner surface 241 of insulator 240 also serves as a shield or seal to contain the plasma within chamber wall 280.

In FIG. 2a, aperture or opening 270 is disposed within anode 220. This is a simple and robust embodiment. However, it will be evident to those skilled in the art that opening 270 could be disposed elsewhere in chamber wall 280, for example, through insulator 240.

FIG. 2b is a schematic representation of another embodiment of a vacuum arc device 400 having an additional opening 290 between the anode and cathode, according to the present invention.

In similar fashion to vacuum arc device 300 shown in FIG. 2a, vacuum arc device 400 includes a source cathode 230, and a substantially non-consumable anode 220. Contained between cathode 230 and anode 220 is an inter-electrode vapor volume 260, through which the arc discharge is effected, and through which plasma from source cathode 230 is transported before ultimately exiting inter-electrode vapor volume 260 via aperture or opening 270.

Inter-electrode vapor volume 260 is contained within a chamber wall 280 made up of at least an inner surface 221 of anode 220 and an inner surface 231 of cathode 230. Unlike vacuum arc device 300, however, cathode 230 and anode 220 are set apart a distance, forming an open area 290 through which plasma within inter-electrode vapor volume 260 is discharged out of vapor volume 260 and chamber wall 280.

Operation of the Inventive Vacuum Arc Devices

Various embodiments of the vacuum arc devices of the present invention may be advantageously operated as follows: during initial (“start-up”) operation, the arc operates in the well known cathode spot mode, producing plasma jets that convey cathode material from cathode 230 into inter-electrode vapor volume 260. In addition, macroparticles from the cathode material are also introduced into inter-electrode vapor volume 260. Thus, during the initial operation (and in the absence of pre-heating), much of the cathode material produced by the arc is deposited on inner surface 221 of anode 220, which may be extremely cool with respect to its steady-state operating temperature.

With time, however, anode 220 is heated by the arc. A sufficiently high arc current is supplied for a sufficiently long time, so as to heat an inner surface 221 of anode 220 to a sufficiently high temperature such that any cathode material previously deposited thereon is evaporated and no further deposition accumulates on inner surface 221.

Unlike the hot refractory anode vacuum arc technology of the prior art, however, the plasma-arc devices of the present invention are adapted to produce a direct, high-quality plasma jet. Without wishing to be limited by theory, we attribute the production of the high-quality plasma jet to the unique constructional features of the inventive devices, including:
a high ratio (“ratio I”) of anode surface area (A_{anode}) to cathode surface area (A_{cathode}) within the plasma-arc chamber, and
a high ratio (“ratio II”) of anode surface area (A_{anode}) to aperture or opening area (A_{openings}) within the plasma-arc chamber.

In the plasma-arc devices of the present invention, the inner surface area of the anode heats up considerably, depending on the evaporation temperature of the particular metal being liberated at the cathode surface. The inner surface area of the cathode attains a much lower temperature, and is usually cooled to an operating temperature below the cathode melting point.

Thus, as ratio I increases, the surface area making up the chamber may achieve a higher overall temperature. Perhaps more significantly, the probability of a given macroparticle colliding with a hot anode area increases, and the heat absorbed by the macroparticle per collision with the hot anode area also increases. The statistical result is that macroparticles formed by the cathode spots will have a greatly increased tendency to evaporate due to wall collisions.

Moreover, as the relative surface area of the cathode decreases, so does the probability that vaporized cathode material will disadvantageously condense on the cathode surface.

With regard to ratio II, as ratio II increases, the chamber becomes an increasingly closed structure, and the relatively low area available for plasma discharge from the chamber results in an appreciable increase in the plasma density (and pressure), and temperature, within the chamber. Consequently, a macroparticle introduced to the chamber will be subjected to, on average, a much higher number of collisions with hotter entities (e.g., plasma, other macroparticles) in the chamber. The increased probability of collision also diminishes the likelihood that a macroparticle entering the chamber could be discharged without undergoing a single collision.

It is manifest from the above that the material utilization efficiency of the vacuum arc deposition system can be enhanced due to complete, or substantially complete, macroparticle evaporation. As the plasma density in the box is high—on the order of 10¹⁶ heavy particles per cubic centimeter (as compared to only about 10¹⁴ heavy particles per cubic centimeter attained in the HRAVA technology), the VABBA source plasma obtained is in the form of an energetic jet.

The structural features of the plasma-arc devices of the present invention are adapted such that the jet discharged from the chamber may be substantially free of macroparticles. Even more surprisingly, and in sharp contrast to the HRAVA devices of the prior art, the jet discharged from the chamber may be substantially free of macroparticles even when the discharge opening is in a line of sight with the cathode spots associated with inner surface 231 of cathode 230.

For the purpose of comparison, a schematic, simplified representation of the HRAVA vacuum arc device 100 of FIG. 1 is provided in FIG. 2c. Anode surface 121 of anode 120 is substantially parallel to cathode surface 131 of cathode 130, and provides a similar geometrical surface area to inter-electrode volume 160. In such HRAVA devices of the prior art, ratio I is typically around 1 or less. In some cases, ratio I is as much as about 1.2.

By sharp contrast, in the VABBA devices of the present invention, ratio I is typically at least 2.0, preferably at least 2.5, more preferably at least 3.5, and most preferably at least 5. In some experimental VABBA devices of the present invention, ratio I is about 7 or more.

Inter-electrode volume 160, though bounded by anode surface 121 and cathode surface 131, can hardly be considered to be contained by a chamber, due to a large opening 161 disposed in perpendicular fashion to surfaces 121 and 131. HRAVA devices are characterized by a low ratio II, i.e., a low ratio of anode surface area (the area of surface 121) to aperture or opening area (the cross-sectional area of opening 161) within the plasma-arc chamber.

This can be demonstrated as follows: using the geometry provided in Example 1 of U.S. Pat. No. 6,391,164 to Beilis et al., the anode surface area (A_{anode}) is defined by πR², where R is the radius of the disk-shaped anode. The opening area (A_{openings}) within the plasma-arc chamber is approximately defined by 2πRh, where h is the space between the anode and cathode. Ratio II simplifies to:

Ratio II=πR²/2πRh=R/2 h

Using the figures provided in the above-referenced Example 1, R is 16 mm and h is 10 mm, such that Ratio II equals 0.8.

By sharp contrast, in the VABBA devices of the present invention, ratio II is typically at least 10, preferably at least 20, more preferably at least 30, yet more preferably at least 50, and most preferably at least 100. In some experimental VABBA devices of the present invention, ratio I is about 150 to 200 or more.

For example, in the single-hole configuration of the inventive device shown in FIG. 2a, Ratio II is approximated by the following relationship:

Ratio II=(2 πhRᵢₙₜπRᵢₙₜ+πRᵢₙₜ²)/πr²=(2 hRᵢₙₜ+Rᵢₙₜ²)/r²

where r is the aperture radius and Rᵢₙₜ is the internal radius of the anode. For a typical device having an external anode radius of 16 mm and an aperture radius of 2 mm, Ratio II is about 200, about 250 times the value obtained for a similar HRAVA device.

The vacuum arc devices of the present invention may have much in common with HRAVA devices, and more particularly with the HRAVA device shown in FIG. 1 and described in detail hereinabove.

FIG. 2d is a schematic, cross-sectional view of the first embodiment of the inventive vacuum arc device 300, shown in greater detail. An electrical arc is ignited between source cathode 230, and substantially non-consumable anode 220. Cathode 230 is preferably cooled, typically by a flow of water, as described with respect to FIG. 1.

Anode 220 is advantageously constructed from a refractory material. Anode 220 is electrically associated with structure 110, which also provides the electrical connection between anode 220 and the rest of the arc circuit. In a preferred embodiment, heat loss by radiation is reduced by surrounding anode 220 by a heat reflector 118. An insulating plate 116 serves both as a heat reflector for the top surface of anode 220, and as an insulator for insulating heat reflector 118 from the anode circuit.

In the present invention, the current required to liberate cathode material in a vacuum-arc mode is at least about 100 A and more typically, 150-400 A.

An electrical insulator 240 is disposed between cathode 230 and anode 220 so as to electrically insulate between these electrodes, as well as to prevent plasma losses from the cathode side. Electrical insulator 240 may advantageously include or consist of boron nitride or other materials whose suitability will be apparent to those skilled in the art.

Structures 110 and 136, which respectively provide mechanical support and electrical connection to anode 220 and cathode 230, are electrically insulated from a surrounding vacuum chamber 101 by insulated feedthroughs 112 and 134. Structures 110 and 136 are connected respectively to the positive and negative poles of a current source, which is not shown. A low voltage current source such as an arc welder may be employed.

Other details of the construction of vacuum arc device 300 will be evident from the description of prior art vacuum arc device 100 of FIG. 1 and from the description of inventive vacuum arc device 300, associated with FIG. 2a.

It will be appreciated by one having ordinary skill in the art that any of various conventional means can be employed to initiate the arc, as the breakdown voltage in vacuum is very high. Conventional means for igniting the arc include imposing a pulse of high voltage between the anode and the electrode, momentarily touching the electrodes and drawing them apart, touching the cathode momentarily with a trigger electrode which initially is at anode potential, imposing a high voltage pulse to a stationary trigger electrode which is separated from the cathode or anode by an insulator and causing a surface flashover, or irradiating one of the electrodes with a laser pulse.

The cathode material from which the metallic plasma is generated may include Cu, Al, Ag, Au, Ti, Ni, Sn, Pb and/or Cr, and other relatively volatile metals and alloys. The anode refractory material may include C, Mo, W and/or Ta and other refractory materials.

### EXAMPLES

Reference is now made to the following examples, which together with the above description, illustrate the invention in a non-limiting fashion.

### Experimental Setup and Methodology

Experimental Apparatus and Electrodes Assembly

Experiments were conducted in a cylindrical vacuum chamber (400 mm length, 160 mm diameter). The chamber was pumped by diffusion pump to about 2×10⁻⁵ Torr. During the arc, the pressure in the chamber was approximately 1 mTorr. The discharge was ignited between a water-cooled copper cathode and a co-axial graphite anode. The anode was produced from graphite (POCO™ DFP-1). The arc currents were I_{arc}=140-245 A, and the arc duration was typically about 150 seconds.

Substrate Preparation, Mounting and Coating Characterization

The substrates were 76×26 mm² glass microscope slides and 20×20 mm² silicon plates. The substrates were pre-cleaned with detergent and dried in compressed air. The substrates were then placed at distance hₛₐₘ=50, 70 mm from the anode surface and were shielded from the depositing plasma flux by a shutter, which was opened for 1 minute beginning at 90 seconds after arc ignition. The film thickness was measured by profilometry. The deposited films were observed using an optical microscope equipped with a digital camera.

### Anode Designs and Experimental Results

Designs of black body anode-cathode assembly were constructed in which the plasma generated from the cathode expands into the mostly closed chamber. During the initial operation, plasma pressure increases with arcing time and macroparticles begin to evaporate in the hot, dense plasma within the chamber. In steady-state operation, the plasma generated from the cathode approximately equals the plasma outflow through at least one small anode aperture or opening. Preferably, the at least one anode aperture has a sufficiently small cross-sectional area such that a relatively high plasma pressure can be attained within the chamber.

Different anode and chamber configurations are described hereinbelow. In all cases, the anode was graphite and the cathode was copper.

### Example 1

### Hollow Anode Having a Single Aperture in the Anode

A simple configuration of the inventive device is schematically provided in FIGS. 2a and 2d, both of which are described hereinabove. A cylindrical hollow graphite anode having an outer diameter of 50 mm (inner diameter=40 mm) was used. The plasma was ejected through a substantially round hole (aperture) passing through the center of the anode and disposed substantially opposite the source cathode surface. The diameter of the hole was 4 mm. The inner surface (opposite the cathode) of the hollow anode was separated at about 10 mm from the source cathode surface.

The cathode, made of copper, had a diameter of 30 mm. A boron nitride shield was disposed between the anode and cathode, and connecting and sealing therebetween, in order to prevent plasma losses from the cathode side.

A visible plasma flux from the hole was observed in the beginning stage of arcing (t<30 s), when the anode was relatively cold. Subsequently, the anode body was heated to higher temperatures and became white. The arc voltage was about 21V during the arc with a current I_{arc} of 170 A.

The distance from the outer anode wall to the substrate was 50 mm. A circular area having a characteristic diameter of about 60 mm was deposited on the substrate, at a maximum deposition rate of about 0.5 μm/min.

FIG. 2e is a photograph showing the discharge of a plasma jet from the vacuum arc device, taken 45 seconds after the initial arc formation.

### Example 2

### Hollow Anode Having a Central Multiple-Hole Insert

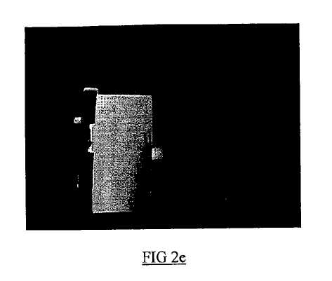

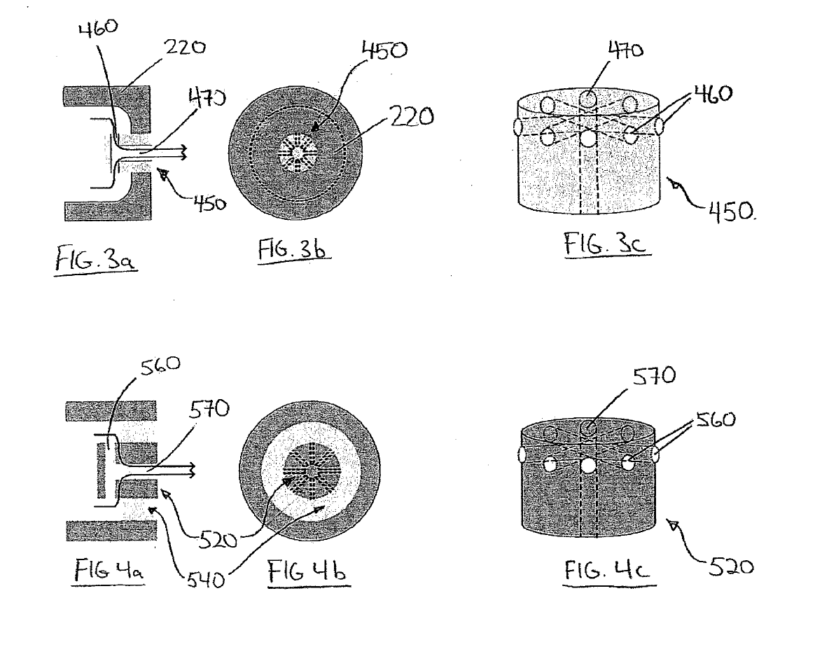

A cylindrical insert (diameter Ø=10 mm) 450, made from boron nitride, was disposed in the inner side of aperture or opening 270 in a hollow anode 220 (Ø=50 mm), as shown schematically in FIG. 3a. The position of insert 450 within anode 220 is shown from another perspective in FIG. 3b. Insert 450, shown alone in FIG. 3c, has 8 small holes 460 (Ø=2 mm) in the radial direction (when insert 450 is disposed in the inner side of opening 270), which join together at or near a blind axial hole 470 (Ø=4 mm), i.e., an axial hole sealed at one end along the cathode-anode axis). The inner surface of hollow anode 220 was set at a distance of about 10 mm from the inner surface of the cathode (not shown). Using this design, all macroparticles ejected from the cathode in the direction of the substrate necessarily collide with insert 450, which serves as a hot reflector.

The arc voltage was about 22V during the initial period of arc production, and then decreased to the steady state about 17V. The macroparticles were not observed on the substrate. The deposition rate was about 0.05 μm/min (I_{arc}=140 A, h=70 mm).

### Example 3

Anode-Cathode Assembly Having Radial Holes in the Anode

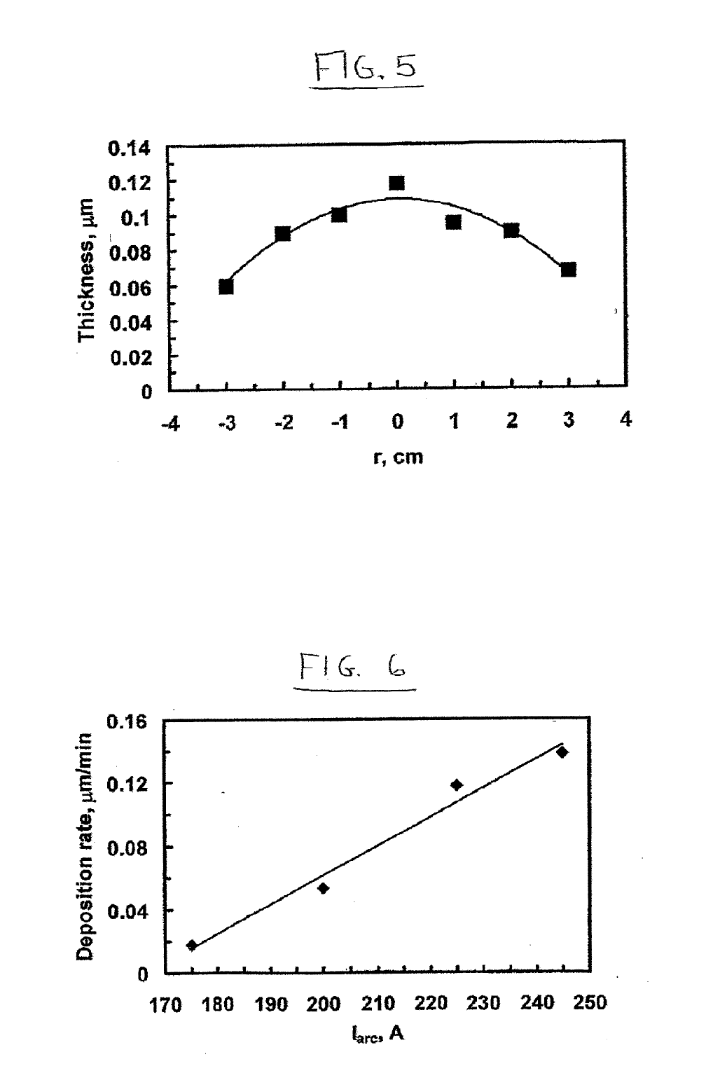

Schematic representations of this embodiment are presented in FIG. 4a-4c. Referring now to these figures, a cylindrical anode 520, made of graphite, is surrounded by an insulation ring 540, made of boron nitride. Cylindrical anode 520 has a diameter of 32 mm. In cylindrical anode 520 are disposed 8 radial holes 560, each having a diameter of 2 mm; and an axial hole 570, having a diameter of 4 mm. The inner surface of the anode was separated from the inner surface of the cathode by about 10 mm. The arc voltage was constant at about 20-21 V throughout the experiment.

The distribution of film thickness vs. r-coordinate (r=0 at the electrode axis) is presented in FIG. 5 (I_{arc}=225 A, h=50 mm). For arc currents from 175 to 245 A, it was observed that:

(1) the film thickness was approximately circular symmetric with maximum at the center r=0;

(2) the characteristic half-width of the film thickness distribution was about 60 mm.

The dependence of deposition rate on arc current (at r=0) is presented in FIG. 6. It is seen that the deposition rate linearly increases with arc current, up to a deposition rate of 0.15 μm/min. The presence of macroparticles on the substrates was essentially not observed.

### Example 4

### Anode Having a Plurality of Small Apertures

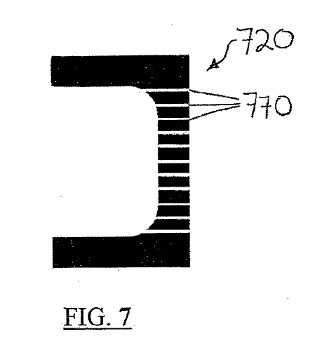

A schematic representation of a preferred embodiment of the inventive (graphite) anode 720 is provided in FIG. 7. About 200 holes 770 were made in the body of graphite anode 720, each hole 770 having a diameter of about 0.5 mm. During operation of the inventive device, the plasma and deposition were uniform on a circular area having a radius about equal to the anode radius. The arc voltage was about 22V during the initial formation of the arc; the arc voltage then decreased to a steady state value of about 17V. Macroparticles were not observed on the substrate surface. The deposition rate was about 0.05 μm/min at I_{arc}=200 A, h=50 nun.

One skilled in the art will recognize that many standard features necessary for the construction of a vacuum deposition system are not detailed or fully detailed herein, such as the means for mounting, heating, and biasing the substrates, flanges and seals on the vacuum chamber, means of evacuating the chamber, means for introducing and regulating a low pressure working gas or reactive gas, etc. These features are well known in the art.

Moreover, although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification, including U.S. Pat. No. 6,391,164, are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A vacuum-arc device comprising:
a consumable cathode including a first material having a defined active surface,
a refractory, substantially non-consumable anode, associated with said cathode, said anode including a second material,
an inter-electrode volume, bounded partially by at least a portion of an inner wall of said cathode and by at least a portion of an inner wall of said anode,
wherein at least a portion of said inner walls form, at least in part, a first chamber surrounding said inter-electrode volume, said chamber having at least one opening fluidly communicating between said inter-electrode volume and an a volume outside said chamber;
a vacuum chamber, disposed around and communicating with said first chamber;
an evacuation mechanism for evacuating said vacuum chamber;
said anode and said cathode for connecting to a high-current power supply,
wherein said cathode is adapted, and said cathode and said anode are disposed, such that upon evacuating said vacuum chamber using said evacuation mechanism, ignition of an arc discharge between said cathode and said anode, and activation of said high-current power supply, a portion of said first material is liberated from said defined active surface of said cathode, transported through said inter-electrode volume, and discharged from said first chamber through said at least one opening,
wherein:
a total opening area of said at least one opening, A_{openings}, is defined by a sum of a minimum cross-sectional area for each said opening, said cross-sectional area being normal to a path of said opening between said inter-electrode volume and said volume outside said chamber;
a surface area of said anode, A_{anode}, is defined by a geometrical surface area of said portion of said anode that bounds said inter-electrode volume;
and wherein a ratio of said surface area of said anode to said total opening area,
A_{anode}/A_{openings}
is at least 10.

2-7. (canceled)

8. The vacuum-arc device of claim 1, wherein said at least one opening passes through said anode.

9. The vacuum-arc device of claim 1, further comprising: at least one insert disposed in said at least one opening, said insert for increasing tortuousity of a path of particles of said portion of said first material as said particles are discharged through said opening.

10. (canceled)

11. The vacuum-arc device of claim 1, wherein said cathode is adapted, and said cathode and said anode are disposed, such that said portion of said first material being discharged through said at least one opening is discharged as a plasma jet.

12. (canceled)

13. The vacuum-arc device of claim 1, further comprising: a mechanism for mounting at least one substrate for coating by plasma discharged through said opening, said mechanism having a defined position for disposing said substrate.

14. (canceled)

15. The vacuum-arc device of claim 1, further comprising: a substrate, disposed in a line of sight of said opening.

16-17. (canceled)

18. The vacuum-arc device of claim 1, wherein a surface area of said cathode, A_{cathode}, is defined by a geometrical surface area of said portion of said cathode that bounds said inter-electrode volume,
and wherein a ratio of said surface area of said anode to said surface area of said cathode,
A_{anode}/A_{cathode}
is at least 2.0.

19-22. (canceled)

23. The vacuum-arc device of claim 1, wherein said ratio of said surface area of said anode to said total opening area is at least 30.

24. The vacuum-arc device of claim 1, wherein said ratio of said surface area of said anode to said total opening area is at least 60.

25. The vacuum-arc device of claim 1, wherein said ratio of said surface area of said anode to said total opening area is at least 100.

26. (canceled)

27. The vacuum-arc device of claim 1, wherein at least one of said at least one opening is outside of a line of sight of said active surface of said cathode.

28. The vacuum-arc device of claim 1, wherein each said at least one opening is outside of a line of sight of said active surface of said cathode.

29. A vacuum-arc device comprising:
a consumable cathode including a first material and having a defined active surface,
a refractory, substantially non-consumable anode, associated with said cathode, said anode including a second material,
an inter-electrode volume, bounded partially by at least a portion of an inner wall of said cathode and by at least a portion of an inner wall of said anode,
wherein at least a portion of said inner walls form, at least in part, a first chamber surrounding said inter-electrode volume, said chamber having at least one opening fluidly communicating between said inter-electrode volume and an a volume outside said chamber;
a vacuum chamber, disposed around and communicating with said first chamber;
an evacuation mechanism for evacuating said vacuum chamber;
said anode and said cathode for connecting to a high-current power supply,
wherein said cathode is adapted, and said cathode and said anode are disposed, such that upon evacuating said vacuum chamber using said evacuation mechanism, ignition of an arc discharge between said cathode and said anode, and activation of said high-current power supply, a portion of said first material is liberated from said defined active surface of said cathode, transported through said inter-electrode volume, and discharged from said first chamber through said at least one opening,
wherein:
a surface area of said cathode, A_{cathode}, is defined by a geometrical surface area of said portion of said cathode that bounds said inter-electrode volume;
a surface area of said anode, A_{anode}, is defined by a geometrical surface area of said portion of said anode that bounds said inter-electrode volume;
and wherein a ratio of said surface area of said anode to said surface area of said cathode,
A_{anode}/A_{cathode}
is at least 2.0.

30. The vacuum-arc device of claim 29, wherein said ratio of said surface area of said anode to said surface area of said cathode is at least 2.5.

31. The vacuum-arc device of claim 29, wherein said ratio of said surface area of said anode to said surface area of said cathode is at least 3.5.

32. The vacuum-arc device of claim 29, wherein said ratio of said surface area of said anode to said surface area of said cathode is at least 5.

33. The vacuum-arc device of claim 29, wherein a total opening area of said at least one opening, A_{openings}, is defined by a sum of a minimum cross-sectional area for each said opening, said cross-sectional area being normal to a path of said opening between said inter-electrode volume and said volume outside said chamber;
and wherein a ratio of said surface area of said anode to said total opening area,
A_{anode}/A_{openings}
is at least 10.

34-35. (canceled)

36. The vacuum-arc device of claim 29, further comprising: at least one insert disposed in said at least one opening, said insert for increasing tortuousity of a path of particles of said portion of said first material as said particles are discharged through said opening.

37-39. (canceled)

40. A method of producing a plasma jet using a vacuum-arc device, the method comprising:
(a) providing a device including:
a consumable cathode including a first material and having a defined active surface,
a refractory, substantially non-consumable anode, associated with said cathode, said anode including a second material,
said cathode and said anode relatively disposed so as to form an inter-electrode volume,
said inter-electrode volume bounded partially by at least a portion of an inner wall of said cathode and by at least a portion of an inner wall of said anode,
wherein at least a portion of said inner walls form, at least in part, a first chamber surrounding said inter-electrode volume, said chamber having at least one opening fluidly communicating between said inter-electrode volume and an a volume outside said chamber;
a total opening area of said at least one opening, Aopenings, is defined by a sum of a minimum cross-sectional area for each said opening, said cross-sectional area being normal to a path of said opening between said inter-electrode volume and said volume outside said chamber;
a surface area of said anode, A_{anode}, is defined by a geometrical surface area of said portion of said anode that bounds said inter-electrode volume;
and wherein a ratio of said surface area of said anode to said total opening area,
A_{anode}/A_{openings}
is at least a predetermined ratio;
(b) at least partly evacuating said chamber;
(c) establishing an arc discharge between said cathode and said anode, using a high-current power supply, such that said discharge produces a vapor, said vapor including vaporized cathode material,
wherein said predetermined ratio is sufficiently high such that substantially all macroparticles from said first material are evaporated prior to being discharged from said first chamber via said at least one opening.

41. The method of claim 40, further comprising:
(d) exposing a substrate to said vaporized cathode material produced by said arc discharge, so as to coat said substrate.

42. The method of claim 19, wherein a ratio of said surface area of said anode to said total opening area,
A_{anode}/A_{openings}
is at least 10.

43. (canceled)

44. The method of claim 19, wherein:
a surface area of said cathode, A_{cathode}, is defined by a geometrical surface area of said portion of said cathode that bounds said inter-electrode volume;
and wherein a ratio of said surface area of said anode to said surface area of said cathode,
A_{anode}/A_{cathode}
is at least 2.0.

45-46. (canceled)

47. The method of claim 40, wherein said ratio of said surface area of said anode to said total opening area is sufficiently high such that a density of heavy particles in said first chamber is at least 2 10¹⁵ particles per cubic centimeter.

48. The method of claim 40, wherein said ratio of said surface area of said anode to said total opening area and said ratio of said surface area of said anode to said surface area of said cathode are sufficiently high such that a density of heavy particles in said first chamber is at least 5 10¹⁵ particles per cubic centimeter.

49. The method of claim 40, wherein said ratio of said surface area of said anode to said total opening area and said ratio of said surface area of said anode to said surface area of said cathode are sufficiently high such that a density of heavy particles in said first chamber is at least 8-10¹⁵ particles per cubic centimeter.

50. A vacuum-arc device comprising:
a consumable cathode including a first material having a defined active surface,
a refractory, substantially non-consumable anode, associated with said cathode, said anode including a second material,
an inter-electrode volume, bounded partially by at least a portion of an inner wall of said cathode and by at least a portion of an inner wall of said anode,
wherein at least a portion of said inner walls form, at least in part, a first chamber surrounding said inter-electrode volume, said chamber having at least one opening fluidly communicating between said inter-electrode volume and an a volume outside said chamber;
said anode and said cathode for connecting to a high-current power supply,
wherein said cathode is adapted, and said cathode and said anode are disposed, such that upon evacuating said chamber, ignition of an arc discharge between said cathode and said anode, and activation of said high-current power supply, a portion of said first material is liberated from said defined active surface of said cathode, transported through said inter-electrode volume, and discharged from said first chamber through said at least one opening, as a thrust-producing plasma jet,
wherein:
a total opening area of said at least one opening, A_{openings}, is defined by a sum of a minimum cross-sectional area for each said opening, said cross-sectional area being normal to a path of said opening between said inter-electrode volume and said volume outside said chamber;
a surface area of said anode, A_{anode}, is defined by a geometrical surface area of said portion of said anode that bounds said inter-electrode volume;
and wherein a ratio of said surface area of said anode to said total opening area,
A_{anode}/A_{openings}
is at least 10.
